(19) United States
(12) Patent Application Publication
(10) Pub. No.: US 2016/0233834 A1
(43) Pub. Date: Aug. 11, 2016

(54) POWER AMPLIFIER FOR COMPENSATING FOR PHASE DELAY CHARACTERISTIC AND APPARATUS OF SYNTHESIZING POWER

(71) Applicant: Electronics and Telecommunications Research Institute, Daejeon (KR)

(72) Inventor: Hong Gu JI, Daejeon (KR)

(21) Appl. No.: 15/041,386

(22) Filed: Feb. 11, 2016

(30) Foreign Application Priority Data
Feb. 11, 2015 (KR) 10-2015-0020704

(51) Int. Cl. H03F 1/02; H03F 3/19; H03F 3/21

(52) U.S. Cl. CPC H03F 1/0205; H03F 3/211; H03F 3/19; H03F 2203/21106; H03F 2203/21142

(57) ABSTRACT

A power amplifier for compensating for a phase delay characteristic and a power synthesizing apparatus using the power amplifier are provided. A microwave frequency amplifying apparatus may include an amplifier configured to amplify a first power and to generate a second power, and a phase shifter configured to compensate for a phase of at least one of the first power and the second power and connected in series to the amplifier.

### CROSS-REFERENCE TO RELATED APPLICATION

This application claims the benefit of Korean Patent Application No. 10-2015-0020704, filed on Feb. 11, 2015, in the Korean Intellectual Property Office, the disclosure of which is incorporated herein by reference.

### BACKGROUND

1. Field of the Invention

Embodiments relate to a technical idea for enhancing a phase delay characteristic of a microwave frequency amplifying apparatus by inserting a phase compensation circuit into the microwave frequency amplifying apparatus when power is synthesized using the microwave frequency amplifying apparatus.

2. Description of the Related Art

Recently, a monolithic microwave integrated circuit (MMIC) has been mainly used as a microwave frequency amplifying apparatus for a reason, for example, a parasitic component, a price or a size.

In particular, when a final stage power amplifier requires high power, MMIC power amplifiers with low power may be connected in parallel and used. However, the MMIC power amplifiers have phase delay characteristics due to an extremely short wavelength in a relatively high frequency band and different characteristics of processes of MMICs.

Accordingly, it is difficult to synthesize power in parallel due to a phase delay characteristic of each of MMIC power amplifiers. For example, it is assumed that power is synthesized without a loss by a power synthesizer with a power amplifier that has a central frequency of “30” gigahertz (GHz) with a gain of “20” decibels (dB) and that does not have a phase delay characteristic and is applied to two different power amplifiers with an input power of “0” decibel-milliwatts (dBm) and the same phase. In this example, an output power by a frequency may be about “23” dBm. However, when a phase difference between the power amplifiers is in the range of “0” degrees to “90” degrees, a maximum power synthesis characteristic difference may be “3” dB.

Due to the above issues, there is a desire for power synthesis between microwave frequency amplifying apparatuses with similar phase delay characteristics.

### SUMMARY

An aspect of embodiments is to enhance a power synthesis characteristic by inserting a proper phase compensation circuit to overcome a degradation in the power synthesis characteristic due to a phase delay characteristic of an amplifying apparatus that desires to synthesize power, in a power synthesizing method of a microwave frequency amplifying apparatus.

Another aspect of embodiments is to facilitate power synthesis between amplifying apparatuses based on a phase delay characteristic during design of a monolithic microwave integrated circuit (MMIC).

According to an aspect, there is provided a microwave frequency amplifying apparatus including an amplifier configured to amplify a first power and to generate a second power, and a phase shifter configured to compensate for a phase of at least one of the first power and the second power, the phase shifter being connected in series to the amplifier.

The first power may be an input power. The phase shifter may be configured to compensate for the phase based on a phase delay characteristic of the microwave frequency amplifying apparatus due to amplifying of the input power.

The microwave frequency amplifying apparatus may include an MMIC.

According to another aspect, there is provided a power synthesizing apparatus including a phase shifter configured to compensate for a phase of each of at least two input powers, an amplifier configured to amplify the at least two input powers with the compensated phase, and a synthesizer configured to synthesize the at least two amplified powers.

The phase shifter and the amplifier may be included in a monolithic microwave frequency amplifying apparatus.

The phase shifter may be configured to compensate for the phase based on a phase delay characteristic of an amplifying apparatus due to amplifying of the at least two input powers.

According to another aspect, there is provided a method of designing a microwave frequency amplifying apparatus, the method including arranging an amplifier circuit configured to amplify a first power and to generate a second power in a pattern layout of a semiconductor chip, and arranging a phase shift circuit configured to compensate for a phase of at least one of the first power and the second power, to be connected in series to the amplifier circuit.

The first power may be an input power. The phase shift circuit may be configured to compensate for the phase based on a phase delay characteristic of the microwave frequency amplifying apparatus due to amplifying of the input power.

The microwave frequency amplifying apparatus may include an MMIC.

According to another aspect, there is provided a method of designing a power synthesizing apparatus, the method including arranging a phase shift circuit configured to compensate for a phase of each of at least two input powers in a pattern layout of a semiconductor chip, connecting an amplifier circuit to the phase shift circuit in series, the amplifier circuit being configured to amplify the at least two input powers with the compensated phases, and arranging a synthesis circuit configured to synthesize the at least two amplified powers.

The phase shift circuit and the amplifier circuit may be included in a monolithic microwave frequency amplifying apparatus.

The monolithic microwave frequency amplifying apparatus may include an MMIC.

The phase shift circuit may be configured to compensate for the phase based on a phase delay characteristic of an amplifying apparatus due to amplifying of the at least two input powers.

According to another aspect, there is provided an operating method of a microwave frequency amplifying apparatus, the operating method including compensating for, by a phase shift circuit, a phase of an input power, and amplifying, by an amplifier circuit, the input power with the compensated phase. The amplifier circuit and the phase shift circuit may be included in an MMIC.

The compensating of the phase may include compensating for the phase based on a phase delay characteristic of the MMIC due to amplifying of the input power.

According to another aspect, there is provided an operating method of a power synthesizing apparatus, the operating method including compensating for, by a phase shifter, a phase of each of at least two input powers, amplifying, by an amplifier, each of the at least two input powers with the compensated phases, and synthesizing, by a synthesizer, the at least two amplified powers.

The phase shifter and the amplifier may be included in a monolithic microwave frequency amplifying apparatus.

The monolithic microwave frequency amplifying apparatus may include an MMIC.

The compensating of the phase may include compensating for the phase based on a phase delay characteristic of an amplifier circuit due to amplifying of each of the at least two input powers.

### EFFECT

According to embodiments, it is possible to enhance a power synthesis characteristic by inserting a proper phase compensation circuit to overcome a degradation in the power synthesis characteristic due to a phase delay characteristic of an amplifying apparatus that desires to synthesize power, in a power synthesizing method of a microwave frequency amplifying apparatus.

Additionally, according to embodiments, it is possible to facilitate power synthesis between amplifying apparatuses based on a phase delay characteristic during design of a monolithic microwave integrated circuit (MMIC).

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 is a block diagram illustrating a microwave frequency amplifying apparatus according to an embodiment;

FIG. 2 is a block diagram illustrating a power synthesizing apparatus using the microwave frequency amplifying apparatus of FIG. 1;

FIG. 3 is a graph illustrating an example of an output power based on a frequency in a power synthesizing apparatus according to an embodiment;

FIG. 4 is a flowchart illustrating a method of designing a microwave frequency amplifying apparatus according to an embodiment;

FIG. 5 is a flowchart illustrating a method of designing a power synthesizing apparatus according to an embodiment; and

FIG. 6 is a flowchart illustrating an operating method of a microwave frequency amplifying apparatus according to an embodiment.

### DETAILED DESCRIPTION

Hereinafter, some embodiments will be described in detail with reference to the accompanying drawings. The scope of the right, however, should not be construed as limited to the embodiments set forth herein. Regarding the reference numerals assigned to the elements in the drawings, it should be noted that the same elements will be designated by the same reference numerals.

Also, terms used herein are selected from general terms being used in the related arts. Yet, the meanings of the terms used herein may be changed depending on a change and/or development of technologies, a custom, or preference of an operator in the art. Accordingly, the terms are merely examples to describe the embodiments, and should not be construed as limited to the technical idea of the present disclosure.

In addition, in a specific case, most appropriate terms are arbitrarily selected by the applicant for ease of description and/or for ease of understanding. In this instance, the meanings of the arbitrarily used terms will be clearly explained in the corresponding description. Hence, the terms should be understood not by the simple names of the terms but by the meanings of the terms and the following overall description of this specification.

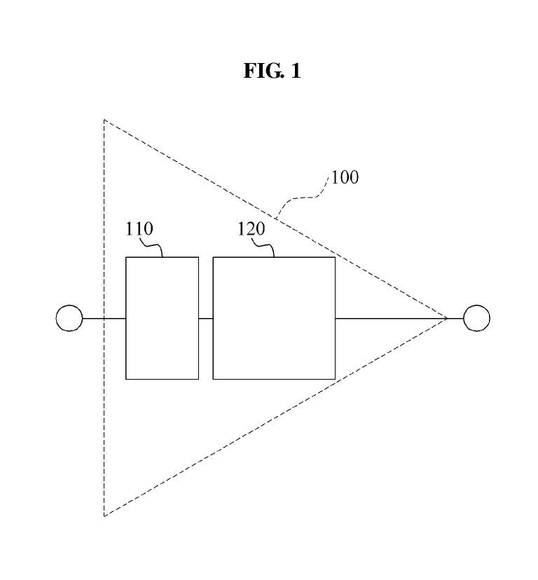

FIG. 1 is a block diagram illustrating a microwave frequency amplifying apparatus 100 according to an embodiment.

The microwave frequency amplifying apparatus 100 may arrange a phase compensation circuit in a front side or a rear side of an amplifier circuit, to compensate for a phase delay characteristic of the microwave frequency amplifying apparatus 100.

### Embodiment 1

In an example, when the phase compensation circuit is located in the front side of the amplifier circuit, reference numerals 110 and 120 of FIG. 1 may be interpreted as a phase shifter and an amplifier, respectively.

In this example, the phase shifter 110 may be connected in series to the amplifier 120, and may compensate for a phase of at least one of a first power and a second power.

The first power may be interpreted as a single input power among at least one input power with the same phase, and the phase shifter 110 may compensate for a phase based on the phase delay characteristic of the microwave frequency amplifying apparatus 100 due to amplifying of the input power.

The amplifier 120 may amplify the first power and generate the second power.

When microwave frequency amplifying apparatuses have the same layout, different phase delay characteristics may be shown. Due to the phase delay characteristics, a maximum difference between amplified second powers may be “3” decibels (dB). The phase shifter 110 may compensate for a phase in the front side of the amplifier 120 so that phase delay characteristics may be maximally similar to each other.

Accordingly, when the phase is closer to “0” degrees, a difference between amplified second powers may also be close to “0.” Thus, the microwave frequency amplifying apparatus 100 including the phase shifter 110 may generate the second power predicable from the first power, instead of being greatly affected by the phase delay characteristic.

### Embodiment 2

In another example, when the phase compensation circuit is located in the rear side of the amplifier circuit, reference numerals 110 and 120 of FIG. 1 may be interpreted as an amplifier and a phase shifter, respectively.

In this example, the amplifier 110 may amplify a first power and generate a second power in the front side of the phase shifter 120.

The phase shifter 120 may be connected in series to the amplifier 110, and may compensate for a phase of the amplified second power. The first power may be interpreted as a single input power among at least one input power with the same phase, and the phase shifter 120 may compensate for a phase based on the phase delay characteristic of the microwave frequency amplifying apparatus 100 due to amplifying of the input power.

Also, the amplifier 110 may amplify a first power and generate a second power. The microwave frequency amplifying apparatus 100 may generate the second power predicable from the first power, using the phase shifter 110, instead of being greatly affected by the phase delay characteristic.

The example in which the phase shifter is located in the front side of the amplifier, and the example in which the phase shifter is located in the rear side of the amplifier have been described above with reference to FIG. 1. Hereinafter, embodiments will be described based on an example in which the phase shifter is located in the front side of the amplifier. However, embodiments are not limited to the example in which the phase shifter is located in the front side of the amplifier, and may be variously interpreted.

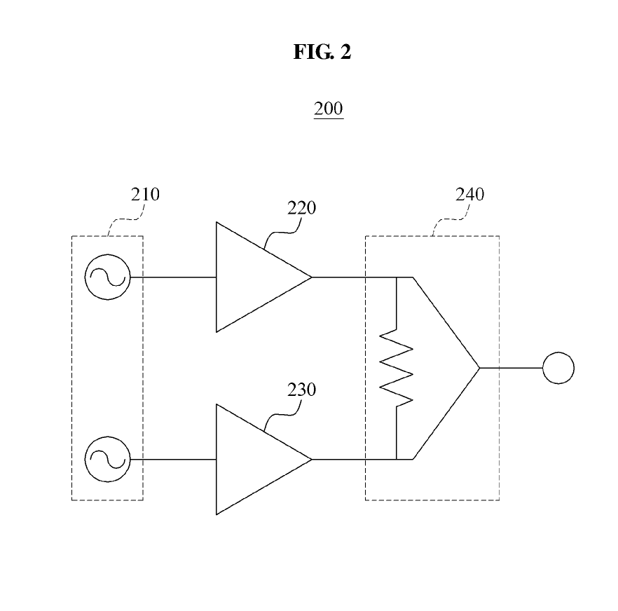

FIG. 2 is a block diagram illustrating a power synthesizing apparatus 200 using microwave frequency amplifying apparatuses 220 and 230 according to an embodiment.

The power synthesizing apparatus 200 may compensate for a phase based on a phase delay characteristic of an amplifying apparatus, to prevent a degradation in a power synthesis characteristic due to the phase delay characteristic.

To this end, the power synthesizing apparatus 200 may include the microwave frequency amplifying apparatuses 220 and 230. The microwave frequency amplifying apparatuses 220 and 230 may have the same configuration as the microwave frequency amplifying apparatus 100 of FIG. 1. The microwave frequency amplifying apparatus 220 may include a phase shifter configured to compensate for a phase of one of input powers 210, and an amplifier configured to amplify an output of the phase shifter. The phase shifter may be located in a front side of the amplifier, may be connected in series to the amplifier, and may compensate for a phase delay characteristic of the microwave frequency amplifying apparatus 220.

Similarly, the microwave frequency amplifying apparatus 230 may include a phase shifter configured to compensate for a phase of the other input power 210, and an amplifier configured to amplify an output of the phase shifter. The phase shifter may be located in a front side of the amplifier, may be connected in series to the amplifier, and may compensate for a phase delay characteristic of the microwave frequency amplifying apparatus 230.

In an example, the microwave frequency amplifying apparatus 220 may include both the phase shifter and the amplifier, and the phase shifter may be located in the front side of the amplifier. In another example, the microwave frequency amplifying apparatus 230 may include both the phase shifter and the amplifier, and the phase shifter may be located in the rear side of the amplifier.

The above examples may differ from each other in that a phase is compensated for after or before power amplification. The microwave frequency amplifying apparatus 220 or 230 may include a monolithic microwave integrated circuit (MMIC).

A synthesizer 240 may synthesize a plurality of input powers that have compensated phase delay characteristics and that are amplified. Accordingly, the synthesizer 240 may output a composite power with a difference between amplified second powers which is close to “0” when a phase is closer to “0” degrees. Thus, the power synthesizing apparatus 200 may generate an output power predictable from the input powers 210, instead of being greatly affected by the phase delay characteristics.

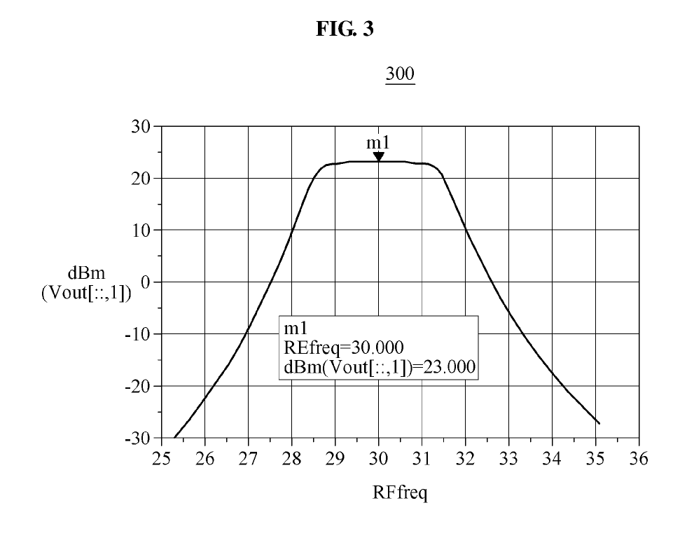

FIG. 3 is a graph 300 illustrating an example of an output power based on a frequency in a power synthesizing apparatus according to an embodiment.

A central frequency of a microwave frequency amplifying apparatus may be “30” gigahertz (GHz), and may have a phase delay characteristic with a maximum phase difference of “90” degrees.

When an input power of “0” decibel-milliwatts (dBm) with the same phase is input, a phase delay characteristic may be compensated for by a phase shift circuit located in a front side of an amplifier circuit in a microwave frequency amplifying apparatus. Accordingly, it is possible to predict an output power by input powers synthesized regardless of the phase delay characteristic in an allowable error range.

Referring to the graph 300 of FIG. 3, because phase delay characteristics of input powers input to different microwave frequency amplifying apparatuses may be compensated for by a phase shift circuit included in each of the microwave frequency amplifying apparatuses, an output power of “23” dBM may be generated regardless of the phase delay characteristics.

Thus, there is no need to synthesize power using microwave frequency amplifying apparatuses with similar phase delay characteristics.

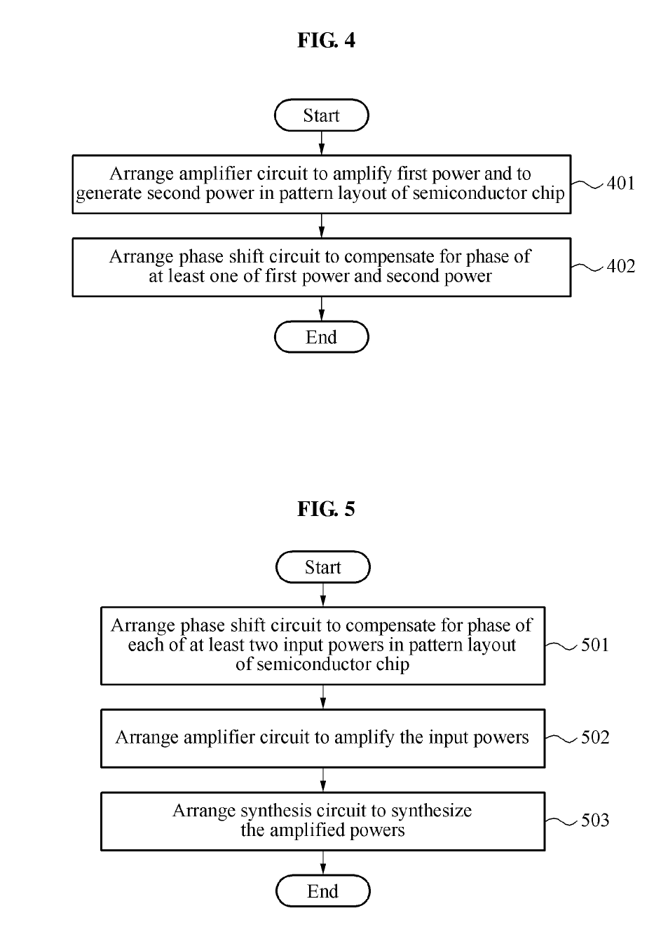

FIG. 4 is a flowchart illustrating a method of designing a microwave frequency amplifying apparatus according to an embodiment.

Referring to FIG. 4, in operation 401, the method may arrange an amplifier circuit configured to amplify a first power and to generate a second power in a pattern layout of a semiconductor chip. In operation 402, the method may arrange a phase shift circuit configured to compensate for a phase of at least one of the first power and the second power, to be connected in series to the amplifier circuit.

The method of FIG. 4 may arrange the amplifier circuit and arrange the phase shift circuit in a front side or a rear side of the amplifier circuit in the pattern layout of the semiconductor chip.

In an example, when the phase shift circuit is located in the rear side of the amplifier circuit, the microwave frequency amplifying apparatus may amplify an input power and may compensate for a delay based on a phase characteristic. In another example, when the phase shift circuit is located in the front side of the amplifier circuit, the microwave frequency amplifying apparatus may compensate for a delay based on a phase characteristic and may amplify an input power.

FIG. 5 is a flowchart illustrating a method of designing a power synthesizing apparatus according to an embodiment.

Referring to FIG. 5, in operation 501, the method may arrange a phase shift circuit configured to compensate for a phase of each of at least two input powers in a pattern layout of a semiconductor chip. In operation 502, the method may arrange an amplifier circuit configured to amplify the at least two input powers with the compensated phases, to be connected in series to the phase shift circuit. In operation 503, the method may arrange a synthesis circuit configured to synthesize the at least two amplified powers.

For example, the method of FIG. 5 may arrange the phase shift circuit and the amplifier circuit to be included in a monolithic microwave frequency amplifying apparatus. In other words, the monolithic microwave frequency amplifying apparatus may function to both compensate for a phase and amplify a power, to compensate for a delay based on a phase characteristic.

The phase shift circuit and the amplifier circuit may be connected in series, and an order of phase compensation and power amplification may change based on an arrangement of the phase shift circuit and the amplifier circuit.

For example, the amplifier circuit may include an MMIC.

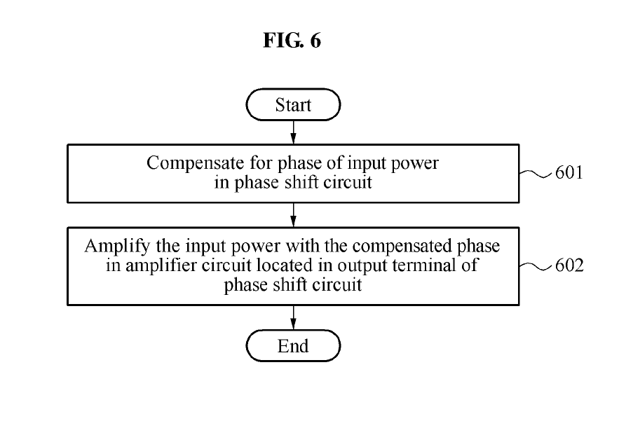

FIG. 6 is a flowchart illustrating an operating method of a microwave frequency amplifying apparatus according to an embodiment.

Referring to FIG. 6, in operation 601, a phase shift circuit may compensate for a phase of an input power. In operation 602, an amplifier circuit may amplify the input power with the compensated phase.

For example, the phase shift circuit and the amplifier circuit may be included in an MMIC. Also, the phase shift circuit and the amplifier circuit may be connected in series to each other, and an order of phase compensation and power amplification may change based on an arrangement of the phase shift circuit and the amplifier circuit.

For example, the operating method of FIG. 6 may compensate for the phase based on a phase delay characteristic of the MMIC due to amplifying of the input power.

At least two microwave frequency amplifying apparatuses may be combined to form a power synthesizing apparatus. The power synthesizing apparatus may synthesize at least two input powers with the same phase regardless of a delay based on a phase characteristic.

To this end, the power synthesizing apparatus may compensate for a phase of each of the at least two input powers, may amplify each of the at least two input powers with the compensated phase, and may synthesize the at least two amplified powers.

As described above, according to embodiments, it is possible to enhance a power synthesis characteristic by inserting a proper phase compensation circuit to overcome a degradation in the power synthesis characteristic due to a phase delay characteristic of an amplifying apparatus that desires to synthesize power, in a power synthesizing method of a microwave frequency amplifying apparatus. Also, it is possible to facilitate power synthesis between amplifying apparatuses based on a phase delay characteristic during design of an MMIC.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A microwave frequency amplifying apparatus comprising:
an amplifier configured to amplify a first power and to generate a second power; and
a phase shifter configured to compensate for a phase of at least one of the first power and the second power, the phase shifter being connected in series to the amplifier.

2. The microwave frequency amplifying apparatus of claim 1, wherein the first power is an input power, and
wherein the phase shifter is configured to compensate for the phase based on a phase delay characteristic of the microwave frequency amplifying apparatus due to amplifying of the input power.

3. The microwave frequency amplifying apparatus of claim 2, wherein the microwave frequency amplifying apparatus comprises a monolithic microwave integrated circuit (MMIC).

4. A power synthesizing apparatus comprising:
a phase shifter configured to compensate for a phase of each of at least two input powers;
an amplifier configured to amplify the at least two input powers with the compensated phase; and
a synthesizer configured to synthesize the at least two amplified powers.

5. The power synthesizing apparatus of claim 4, wherein the phase shifter and the amplifier are included in a monolithic microwave frequency amplifying apparatus.

6. The power synthesizing apparatus of claim 5, wherein the monolithic microwave frequency amplifying apparatus comprises a monolithic microwave integrated circuit (MMIC).

7. The power synthesizing apparatus of claim 4, wherein the phase shifter is configured to compensate for the phase based on a phase delay characteristic of an amplifying apparatus due to amplifying of the at least two input powers.

8. An operating method of a microwave frequency amplifying apparatus, the operating method comprising:
compensating for, by a phase shift circuit, a phase of an input power; and
amplifying, by an amplifier circuit, the input power with the compensated phase,
wherein the amplifier circuit and the phase shift circuit are included in a monolithic microwave integrated circuit (MMIC).

9. The operating method of claim 8, wherein the compensating of the phase comprises compensating for the phase based on a phase delay characteristic of the MMIC due to amplifying of the input power.
